(19) United States
(12) Patent Application Publication
(10) Pub. No.: US 2015/0142344 A1
(43) Pub. Date: May 21, 2015

(54) METHOD AND APPARATUS FOR MEASURING PARTIAL DISCHARGE CHARGE VALUE IN FREQUENCY DOMAIN

(71) Applicant: UTILX Corporation, Kent, WA (US)

(72) Inventors: Jun Guo, Issaquah, WA (US); Wen Shu, Issaquah, WA (US); Oscar E. Morel, Seattle, WA (US)

(73) Assignee: UTILX CORPORATION, Kent, WA (US)

(21) Appl. No.: 14/517,486

(22) Filed: Oct. 17, 2014

Related U.S. Application Data
(60) Provisional application No. 61/893,120, filed on Oct. 18, 2013.

(51) Int. Cl. G01R 31/12; G01R 29/24

(52) U.S. Cl. CPC G01R 31/12; G01R 29/24
USPC 702/58

(57) ABSTRACT

The charge value of a partial discharge pulse in an electrical cable is provided by analyzing the frequency spectrum of the propagated pulse in a spectrum analyzer 21 to generate sets of spectrum signals, each including a magnitude and a frequency of a component of the pulse. A laptop computer has a processor, receives the spectrum signals, and has one or more application computer programs operable to perform the calculations of Equations 2-6, finds the bandwidth and energy of the spectrum signals from which the computer programs derive unknown time domain parameters including the maximum value of the pulse and the time interval of the pulse at half its maximum value. With those parameters, the program reconstructs a time domain signal of the pulse and integrates that signal to provide the charge value of the partial discharge.

### CROSS-REFERENCE TO RELATED APPLICATION

This application claims the benefit of Provisional Application No. 61/893,120, filed Oct. 18, 2013, the disclosure of which is hereby incorporated by reference herein.

### BACKGROUND

Partial discharge (PD), by definition, is a localized breakdown of a defect within the insulation that does not bridge the electrodes. PD is a phenomenon that occurs within imperfections of the insulation in electrical equipment such as power cables and gas insulated electrical devices. A typical PD signal in a solid insulation is a current pulse with very short duration, e.g., a few nanoseconds, and has an initial bandwidth in the GHz range. PD may result from initial voids and contaminants in the insulation material and physical and chemical changes that occur over time due to thermal, mechanical or electrical stresses.

PD degrades the insulation system over time. While any one PD is not critical, over time the PDs at any given defect or void may grow until it becomes a serious problem that could interrupt operation of the equipment, cause unexpected breakdowns and result widespread and possible catastrophic failure of an electrical distribution network.

Therefore, PD testing is considered as one of the more effective diagnostic approaches to evaluate the insulation condition of electrical equipment. Systems and services are available to record partial discharges and other emissions and analyze them to assess the insulation condition. PDs may be detected in time domain or frequency domain, while the equipment is online or offline. PD signals are captured normally using either PD couplers that connect to the test object in offline test or using PD sensors that do not directly contact the test object in online test. The captured data is then fed into a data acquisition device (e.g., frequency spectrum analyzer in frequency domain test, or oscilloscope in time domain test) to derive a number of valuable measurements. During an online PD cable inspection, data acquisition begins by placing a radio frequency (RF) sensor over the exterior of an energized shielded cable. This cable remains in service and does not have to be isolated from the system. Once PD occurs, the PD induced RF signals propagated in the cable are detected, amplified, and then recorded on a laptop computer. The data are analyzed to determine the condition of the cable system, including all cable sections and their associated splices and terminations.

In PD data analysis, the strength of the PD is the magnitude of the charge value of the PD. However, since the discharge occurs inside of the insulation, the physical magnitude of the discharge (“real discharge”) cannot be measured without the knowledge of the equipment under test (EUT) and the geometries of the defect. Instead, the “apparent discharge” is presented as current or voltage pulses in an external circuit connected with the EUT and those pulses can be measured and quantified. In this document, the discharge magnitude refers to this measurable “apparent discharge.” The measured PD is preferred to be present in this charge value (in the unit of pico-coulumb, pC), because different test instruments tend to get different readings depending on their gain and the response of the test instruments, but the charge value for the measured PD event should be identical. The objective of presenting the measured PD result in pC value is to ensure the measured apparent discharge magnitude for the same defect in a EUT is identical with different test equipment.

The PD charge value is derived from the measured PD current or voltage pulses. One approach to obtain the charge value is to integrate the current pulse in time domain. However, as discussed in Reference [3], that integration method is not practical in field measurement, as the time constant needed to achieve a correct charge value is too large and makes the integration very complex and difficult. FIG. 1A gives the current waveform of a 96 pC pulse measured by a 1 nF capacitive coupler in laboratory, and the corresponding charge value obtained by integrating the measured current waveform is in FIG. 1B. From FIG. 1A, even in a laboratory environment, the integrating time that is required to obtain the charge value is 300 ns. In a field test, there is more resonance in the FIG. 1A waveform, which requires even longer integrating time in FIG. 1B, and there is so much interference with measurement that such integration is virtually impossible.

Another approach to quantify the charge in time domain PD measurement is through the “calibration” procedure. Since the magnitude of the PD induced current (or voltage) pulse is much easier to quantify, the calibration procedure was introduced in the IEC60270 and IEEE 400.3 standards (References [1] and [2], respectively) to establish the relationship between the measured PD current magnitude and the apparent discharge in pC value. The conventional calibration procedure requires injecting a calibration pulse with a known magnitude of charge into the EUT, and measuring the calibration pulse with the PD test equipment. The ratio between the magnitude of the measured calibration pulse (current or voltage) and the injected pC value is the calibration coefficient, and any measured PD pulse can be converted into the pC value by multiplying this calibration coefficient.

Unfortunately, not all the PD testing equipment can be calibrated with the above procedure. Online PD testing measures PD when the EUT is in service, in which accessing a conductor within a cable is impossible. Therefore, the conventional calibration approach which injects a calibration pulse into the EUT is not feasible. Hence, online PD testing is normally considered as an “un-calibratable” method. Even for offline tests where injecting a calibration pulse is practical, some PD test equipment still cannot be calibrated, depending on the detection bandwidth, center frequency, and the frequency characteristics of the measured PD signals. A. Cavallini and G. C. Montanari in Reference [3] summarized PD calibration of various types of testing equipment. It is conventional to expect PD test equipment can be calibrated only if its testing frequency range is lower than the upper cutoff frequency of the measured PD signal.

FIG. 2 is a reproduction of FIG. 1 of Reference [3] and illustrates the frequency spectra for three pulses, each with the same apparent discharge magnitude and the same upper cutoff frequency (fc) but different decay rates in higher frequency regions. The hatched areas, labeled as A, B, C, represent the bandwidths for three bandpass filters, each with the same bandwidth but differing center frequency. The measured energies for the three pulses with Filter A are the same, but the energies measured with Filters B and C are different from Filter A and from each other. Accordingly, the measured pulse energy has different values which depend upon the characteristics of the frequency response of the measuring equipment. In practice, ultra wide band (UWB) PD test equipment performing PD measurement in the time domain can be calibrated, as it has a lower cutoff frequency close to DC and an upper cutoff frequency lower than the f_{c} of the measured PD signal. But the ultra-high frequency (UHF) PD test in time domain, which features high center frequency but narrow bandwidth, cannot be calibrated because its measuring frequency range drops above the f_{c} of the measured PD signal.

Frequency domain PD tests which use a spectrum analyzer for measurement cannot be calibrated with conventional methods, because a frequency domain test is considered to be the UHF PD test described above. The testing bandwidth is in the range of few MHz but the center frequency varies from few MHz up to hundreds of MHz, as moving the bandpass Filter A from the most left of FIG. 2 to the most right. Accordingly, it is impossible to perform calibration for frequency domain PD testing with current techniques regardless of whether the test is online or offline.

In summary, coulomb charge value of a PD pulse cannot be measured directly. Conventional integrating of PD current pulse in time domain to obtain the coulomb charge value is very difficult in field tests due to interferences and the requirement for a long integration time. The alternative calibration approach is also performed in time domain, which only provides reliable results on devices taken out of service, and even then there are limits on the types of testing instruments which can be calibrated. There is no method or apparatus for measuring coulomb charge value in frequency domain, and there is no method or apparatus for measuring coulomb charge value when the tested devices are in service.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

Applicants have invented a new method and apparatus that provides reliable measurements of PD in cables and power equipment, devices and conductors while each is online. This method and apparatus converts measured voltage values and frequencies from PD test equipment into a charge value in pC. The method is carried out with a processor and with frequency domain measurements acquired with a spectrum analyzer. The method converts the measured frequency spectrum of the PD signal into time domain with certain reasonable assumptions, and generates a virtual or reconstructed time domain PD current pulse. The virtual PD current pulse does not contain interference and has a Gaussian waveform which is easily integrated to obtain the charge value representative of PD. Since no calibration pulse is required to be injected in the EUT, the method is particularly beneficial for online PD testing.

The method and corresponding apparatus of the invention measures a partial discharge in a device such as a cable or other equipment by detecting a PD pulse that occurs in the insulation of an EUT. Experience has shown that PD pulses in cables and other power equipment such as switchgears, arresters, insulators, etc., have an initial shape that closely resembles a Gaussian function.

A spectrum analyzer provides output signals of the magnitude and frequency of each of the component sinusoidal signals of the PD voltage pulse signal. Those skilled in the art know that any signal may be transformed into component sinusoidal signals by means of a Fourier transform. A processor receives the output signals of the spectrum analyzer, uses the outputs of the spectrum analyzer to calculate the bandwidth and energy of the frequency spectra and then calculates the maximum pulse value and the full pulse width interval at half maximum value (FWHM) of the pulse. From those calculations, the processor derives a signal representative of the time domain voltage pulse signal, converts the voltage pulse signal into a current pulse signal, and integrates the current pulse signal over the duration of the pulse to provide a charge value representative of the charge that is discharged at the defect. As a result, the method and the apparatus of the invention measures PD in coulombs in devices online using the frequency spectra of the PD pulse.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A is a graphical representation of a current pulse generated by a PD in the insulation of an electrical cable;

FIG. 1B is a graphical representation of the total charge generated by the PD of FIG. 1A;

FIG. 2 is a graphical representation of PD spectra measured with apparatus using different frequency ranges for a bandpass filter;

FIG. 3 is a graphical representation of a partial discharge pulse in an electrical cable;

FIG. 4 is a combined block diagram and flow chart of the apparatus and steps of the process for measuring charge of a partial discharge in an electrical cable;

FIG. 5 is a graphical representation of the time domain signature of a partial discharge pulse; FIG. 6 is graphical representation of the frequency spectrum of the partial discharge pulse of FIG. 5; and

FIG. 7 is a comparison of the partial discharge pulse of FIG. 5 and a reconstructed partial discharge pulse generated by the method of FIG. 4.

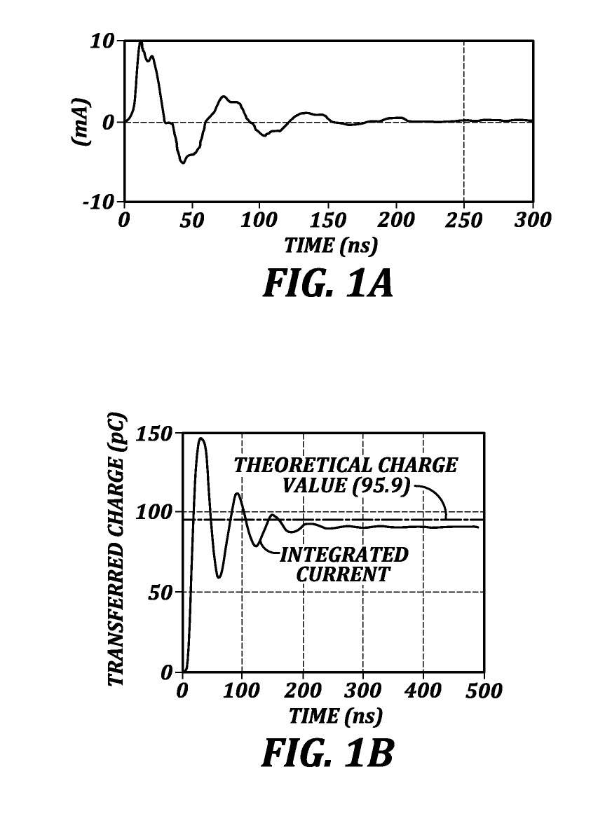

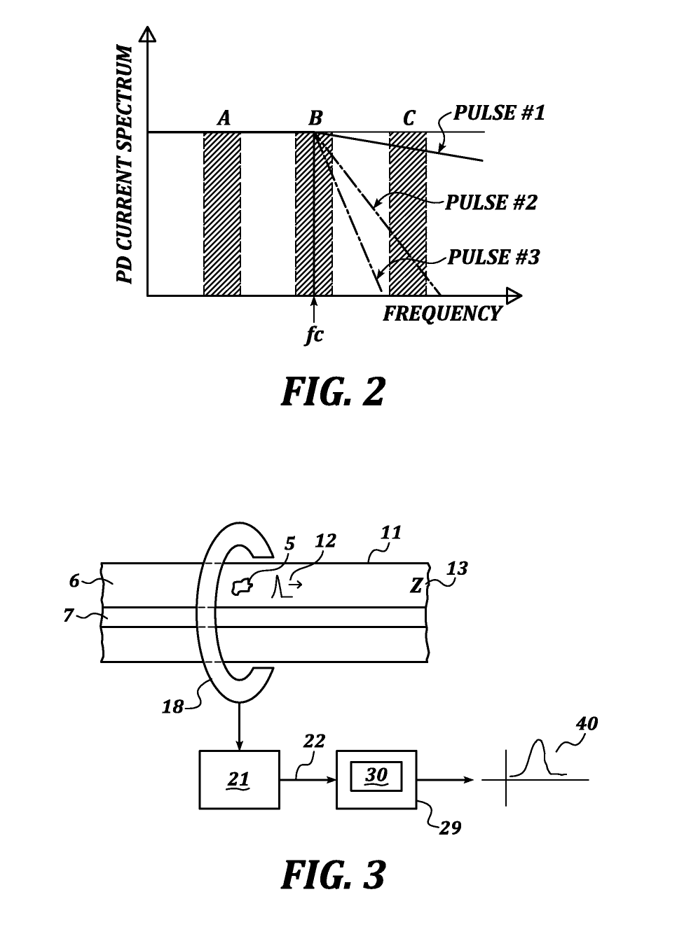

### DETAILED DESCRIPTION

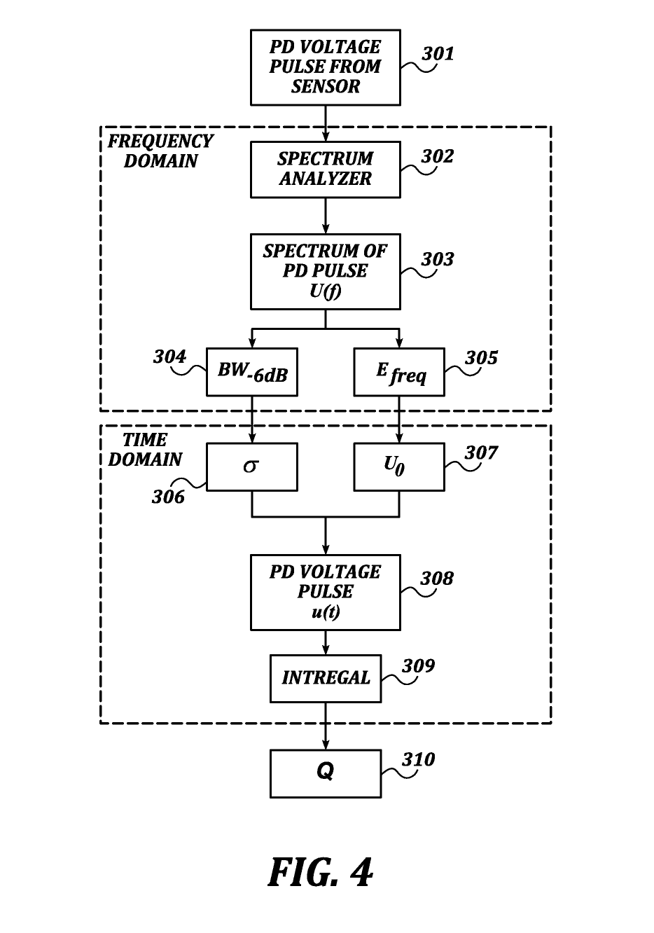

Turning to FIG. 3, a cable 11 has a central conductor 7 for carrying current. The conductor 7 is surrounded by insulation 6 with impedance, Z, 13 and a defect 5 in the insulation. When voltage that is applied across the defect 5 in the insulation 6 reaches a partial discharge inception voltage, defect 5 generates a partial discharge (PD) 10 and PD 10 propagates a current signal 12 along the cable 11. An RF sensor 18 placed proximate the cable 11 detects the current PD signal 12 in the cable. In a preferred embodiment, the sensor 18 is directly connected to an analog swept frequency analyzer 21 which generates a set of output frequency spectra signals 22 representative of the frequency spectrum of the current pulse 12. The analog spectrum analyzer 21 mixes the input signal 12 with a sinusoidal signal with varying frequency that is generated by a local oscillator and feeds the mixed signal through a bandpass filter. The output of the bandpass filter at a certain frequency of the local oscillator gives one frequency component of the input signal. The spectrum signals 22 include the magnitude and frequency of each component of the PD pulse 12. The spectrum analyzer 21 digitizes the output signals for input to a laptop 29.

The laptop 29 includes input ports for receiving external inputs such as the frequency spectrum signals 22. It also has user input means including and not limited to a mouse, keyboard or trackball device, a central processing unit such as a microprocessor 30, one or more memories for holding data and programs including operating system programs and application programs. The input means, memories, operating system program, and display are conventional components of a laptop computer and are not individually shown. The application programs are described below in connection with Equations 2-6.

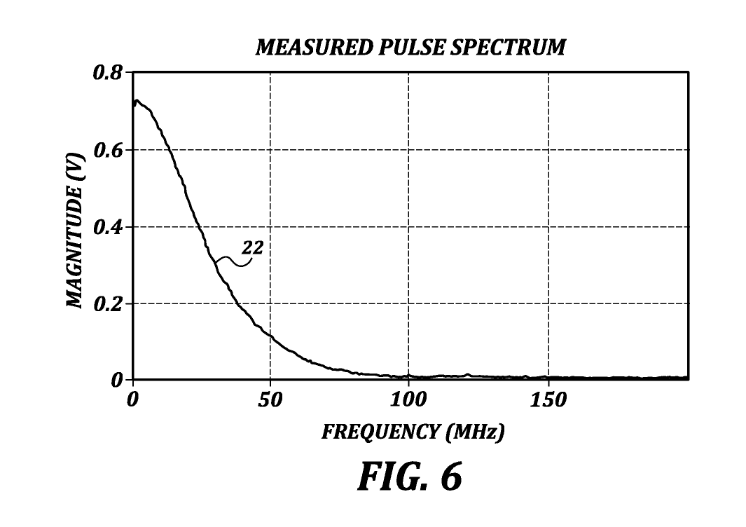

The processor 30 processes the frequency spectrum signals 22 in accordance with one or more programs stored in a memory of the laptop 29 and generates an output 40 representative of the charge in pico-Coulombs of the PD 10. The method described herein assumes the PD pulse has a Gaussian form or a form that closely resembles Gaussian form. The Gaussian or Gaussian-like PD pulse 10 (FIG. 5) and the resulting current pulse 12 are signals that have very short lives and also a broad spectrum. The spectrum analyzer 21 receives a coil output signal 12′ that is representative of the time domain current pulse 12 and provides output frequency spectra signals 22 which are a set of spectral lines including the amplitude and frequency of each of the components of the sensed pulse 12. The spectrum analyzer generates output frequency spectra signals 22 by using a narrow resolution bandwidth filter to detect each frequency component and its magnitude. The frequency spectrum signals 22 are inputs to processor 30. Since the signal 10 was Gaussian, the frequency spectrum 22 is also Gaussian in the frequency domain. See FIG. 6.

For demonstrating the operation of the invention, the PD pulse 10 is simulated with a Gaussian pulse in time domain. The measured frequency spectrum 22 of pulse 12 also has a Gaussian distribution. This assumption is consistent with observed phenomena of PDs.

The Gaussian pulse 10 can be represented as

$$u ( t ) = {U}_{0} \cdot {e}^{- \frac{{( t - {t}_{0} )}^{2}}{2 {σ}^{2}}} \qquad ( EQ \text{-} 1 )$$

where U₀ is the pulse magnitude, t₀ is the center of the pulse which can be assumed to be 0, and 2.36σ is the full width of the time interval between the half maximum values (FWHM) of the Gaussian pulse. The values of U₀ and σ are unknown and cannot be directly sensed from the pulse signal 12. However, we discovered that the unknowns can be derived by reconstructing a time domain signal of the PD pulse from the frequency spectrum signals 22. The value of σ value can be obtained from the measured signal bandwidth in frequency domain as shown in Reference [4] whose entire contents is hereby incorporated by reference, as

$$σ = \frac{\sqrt{2 \cdot ln ( 2 )}}{2 π \cdot {BW}_{- 6 dB}} \qquad ( EQ \text{-} 2 )$$

where BW_{-6dB} is the −6dB bandwidth that can be measured with spectrum analyzer.

Since energy is conserved, the measured energy of the PD pulse is the same in both time and frequency domains. In time domain, the energy of the PD pulse is

$${E}_{time} = \int \frac{{( u ( t ) )}^{2}}{{Z}_{load}} d t = {U}_{0}^{2} \int \frac{1}{{Z}_{load}} \cdot {e}^{- \frac{{t}^{2}}{{σ}^{2}}} d t \qquad ( EQ \text{-} 3 )$$

The pulse energy in the frequency domain is the integral of the measured power per unit frequency over the scanned frequency range, as

$${E}_{freq} = {\sum }_{i} \frac{{P}_{i}}{RBW} = {\sum }_{i} \frac{{( {U}_{i} ( f ) )}^{2}}{{Z}_{load} \cdot RBW} \qquad ( EQ \text{-} 4 )$$

where RBW is the resolution bandwidth of the spectrum analyzer, Z is impedance of the cable, Pᵢ is the measured power at the i^{th} frequency, and Uᵢ (f) is the measured voltage at the i^{th} frequency. Combining EQ-3 and EQ-4 and solving for U₀, the pulse magnitude in time domain is

$${U}_{0} = \sqrt{{E}_{freq} \cdot {( \int \frac{1}{{Z}_{load}} \cdot {e}^{- \frac{{t}^{2}}{{σ}^{2}}} d t )}^{- 1}} \qquad ( EQ \text{-} 5 )$$

With EQ-2 and EQ-5, the two unknowns in EQ-1 can be obtained from the frequency domain measurement, thus the time domain PD pulse can be reconstructed with EQ-1, and the charge is the integral of the corresponding current as

$$Q = \int \frac{u ( t )}{{Z}_{load}} d t \qquad ( EQ \text{-} 6 )$$

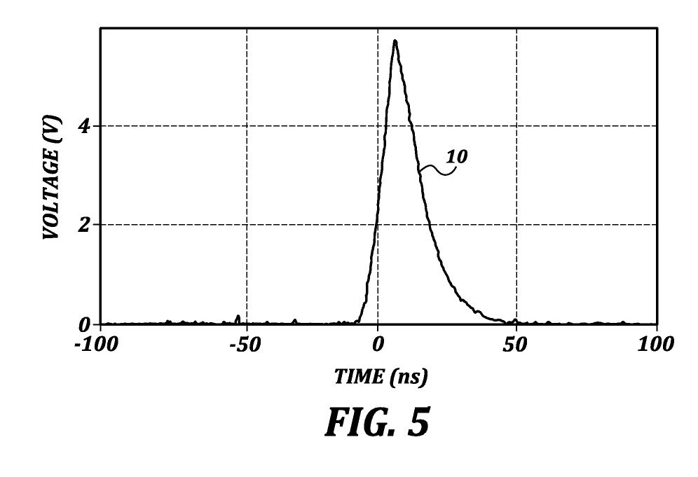

FIG. 4 shows the apparatus and steps of an exemplary method for measuring charge of a partial discharge in the cable 11. The PD pulse 10 is generated in a cable 11 having predetermined impedance 13, Z and propagates as a pulse signal 12. In step 301 an RF pulse sensor 18 senses the pulse signal 12′ propagated in the cable 1. In step 302 the signal 12′ is directly coupled to the input of the spectrum analyzer 21. In step 303 the spectrum analyzer deconstructs the pulse signal 12′ into its frequency spectrum 22, as shown in FIG. 6, and outputs a set of frequency spectrum signals 22 having a Gaussian distribution.

In steps 304, 305, the processor 30 uses one or more application programs to carry out the calculations of EQ-2 and EQ-4, respectively, to calculate the bandwidth 24 and the energy 25 of the frequency spectra 22. In steps 306 and 307, respectively, the processor 30 operates one or more applications programs to derive the unknown time domain parameters including the maximum value of the pulse U₀ and the time interval 2.36σ of the pulse at half its maximum value. These steps are equivalent to performing the calculations of EQ-5 and EQ-6, respectively, to calculate σ (31) and the maximum value U₀ (32). In step 308 the processor 30 generates a derived time domain signal u (t) of the pulse signal 12 from EQ-1 using the derived and previously unknown values of σ and U₀ found in prior steps 306 and 307. The impedance 13 (Z) of the cable is either known or measurable. Voltage is the product of current and impedance or V=I×Z so that I=V/Z. It is also known that charge is the integral of current over time, which is shown in EQ-6. In step 309 the processor 30 operates one or more applications programs to perform the integration of EQ-6. The results are the output 40 and include the magnitude of the charge of the input pulse 10 and a visual representation of the time domain pulse, if so desired.

In one exemplary embodiment, it was assumed there was a Gaussian partial discharge of 1,991 pC in the cable. The time domain signature of the pulse 10 is shown in FIG. 5. The spectrum signals 22 of the resulting voltage pulse 10 are shown in FIG. 6. The processor 30 used the spectrum signals 22 to calculate a value 25.8 MHz at −6dB for the bandwidth 24 and a value of 6.974 nJs for the spectrum energy 25. The processor 30 calculated a value for a of 7.263 ns in step 31 and a value for U₀ of 5.204 V in step 32.

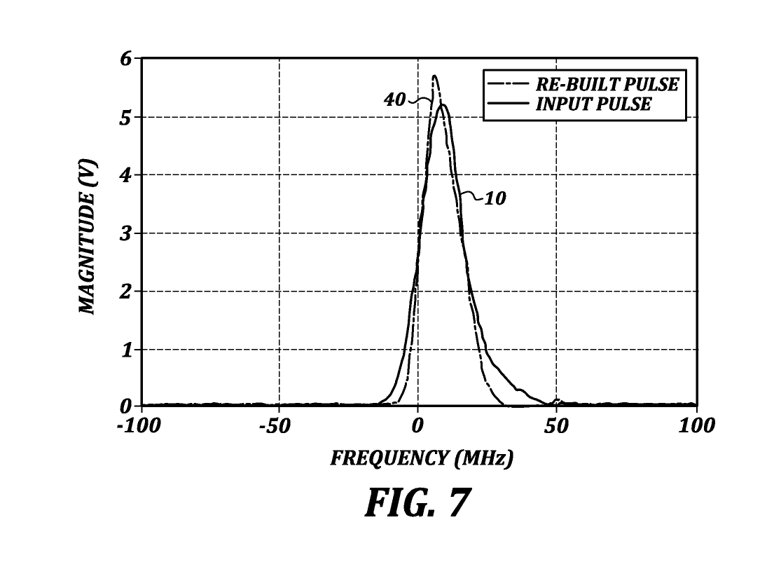

FIG. 7 shows a reconstructed time domain pulse 38 (step 308) with the original PD pulse 10 for comparison. The charge in the reconstructed pulse 38 is 1,895 pC. It was computed with EQ-6 by integrating the reconstructed current waveform 38 in the time domain. Its value of 1,895 pC is only slightly different from the assumed PD of 1,991 pC, a minor difference of 4.8%.

An alternate method and apparatus performs a capture-and-store method. In that technique, the pulse signal 12 from the sensor is input to an analog-to-digital converter and stored in a memory for later access and processing. As an alternative, the digitized signal 12′ may be transmitted via wired or wireless communication to the laptop 29 where it is stored in a memory. The spectrum of the signal can be processed later with a suitable algorithm (for example, Fourier transform) by laptop 29 in a manner similar to the way a digital spectrum analyzer works.

A further alternative substitutes a digital spectrum analyzer for the analog analyzer 21. The digital spectrum analyzer combines a fast analog-to-digital converter, storage, and Fourier transform processor (a computer that performs Fourier transform) to generate frequency spectrum signals 22. The digital spectrum analyzer has functions identical to the analog swept frequency analyzer, i.e., both of which give signal spectrum as output. The structures of these two analyzers are very different. As explained above, an analog spectrum analyzer mixes an input signal with a local oscillator which generates sinusoidal signals with varying frequencies (swept frequencies), and feeds the mixed signal through a bandpass filter. The output of the bandpass filter at a certain frequency of the local oscillator gives one frequency components of the input signal. The digital spectrum analyzer uses a fast analog-to-digital converter to digitize the input data, and uses fast Fourier transforms to obtain every frequency components of the input signal.

The foregoing demonstrates that voltage pulses resulting from Gaussian partial discharges can be captured and analyzed in the frequency domain to discover unknown characteristics of their time domain signals that cannot be deduced or processed from time domain signals and the time domain signals can be reconstructed from those components and the charge value of the partial discharge can be calculated. This provides the cable operator with valuable information about the charge value of partial discharges which in turn allow the operator to better assess the condition of the insulation in a cable. With the method and apparatus described above, cables may be remotely inspected by taking sample readings at one or more locations with RF sensors 18 and sending those readings and location date to a central location such as a laptop 29.

While illustrative embodiments have been illustrated and described, it will be appreciated that various changes can be made therein without departing from the spirit and scope of the invention.

### REFERENCES

[1]. IEC 60270
[2]. IEEE 400.3
[3]. A. Cavallini, G. Montanari, and M. Tozzi, “PD Apparent Charge Estimation and Calibration: a Critical Review,” IEEE Trans. on Dielectric and Electrical Insulation 17(1):198-205, 2010.
[4]. Jim Guo, Lili Zhang, Chunchuan Xu, and Steven Boggs, “High Frequency Attenuation in Transmission Class Solid Dielectric Cable,” IEEE Trans. on Power Delivery 23(4):1713-1719, 2008.
[5]. Steven Boggs, “The Case for Frequency Domain PD Testing in the Content of Distribution Cable,” IEEE Electrical Insulation Magazine 19(4):13-19, 2003.

1. A method for measuring the charge of a partial discharge (PD) pulse comprising the steps of:
receiving a PD voltage pulse;
analyzing the PD voltage pulse to generate frequency spectrum signals wherein each frequency spectrum signal includes a magnitude and frequency;
processing said frequency spectrum signals to generate signals representative of
(a) the maximum magnitude of the PD voltage pulse; and
(b) the time interval of the PD voltage pulse at half the maximum (FWHM) value of the PD voltage pulse;
generating a time domain signal representative of the PD voltage pulse from the derived full width at half the maximum value of the pulse and the derived maximum value of the PD pulse;
for predetermined impedance, integrating the PD voltage pulse over time to generate a signal representative of magnitude of the charge in the PD pulse.

2. The method of claim 1 wherein said processing step comprises the steps of:
measuring bandwidth of the frequency spectrum signals;
from said bandwidth, deriving the signal representative of full width at half the maximum value of the PD pulse (FWHM);
deriving a magnitude of energy of said frequency spectrum signals;
deriving the maximum magnitude of the PD voltage pulse from the magnitude of energy of said frequency spectrum signals.

3. The method of claim 1, further comprising the step of converting the PD pulse to a digital format and storing the digital format for latter frequency analysis.

4. A method for measuring the charge of a partial discharge (PD) pulse in an electrical cable while said cable online and part of an electrical energy distribution system, comprising the steps of:
sensing a PD voltage pulse in said electrical cable while said electrical cable is online;
analyzing the PD voltage pulse to generate frequency spectrum signals wherein each frequency spectrum signal includes a magnitude and frequency;
measuring bandwidth of the frequency spectrum signals;
deriving a signal representative of full width at half the maximum value of the PD pulse (FWHM) from the bandwidth measurement;
deriving a magnitude of energy of said frequency spectrum signals;
deriving a maximum magnitude of the PD voltage pulse from the magnitude of energy of said frequency spectrum signals;
generating a time domain signal representative of the PD voltage pulse from the derived full width at half the maximum value of the pulse (FWHM) and the derived peak value of the PD pulse;
for predetermined impedance, integrating the PD voltage pulse over time to generate a signal representative of magnitude of the charge in the PD pulse.

5. The method of claim 4 wherein the PD pulse has a Gaussian form.

6. The method of claim 4 wherein the PD voltage pulse is analyzed with a spectrum analyzer to provide the magnitude and signals in the frequency spectrum.

7. An apparatus for method for measuring the charge of a partial discharge (PD) pulse in an electrical cable online as part of an electrical energy distribution system, comprising:
a sensor for detecting a PD pulse in said online electrical cable;
a spectrum analyzer coupled to the sensor for receiving the PD voltage pulse and for generating frequency spectrum signals wherein each frequency spectrum signal includes a magnitude and frequency;
a processor having a central processing unit, one or more memories, and programs stored in the one or more memories for operating the processor and for:
calculating bandwidth from the frequency spectrum signals;
calculating full width at half the maximum value of the PD pulse (FWHM) from the bandwidth measurement;
calculating a magnitude of energy of said frequency spectrum signals;
calculating a maximum magnitude of the PD voltage pulse from the magnitude of energy of said frequency spectrum signals;
generating a time domain signal representative of the PD voltage pulse from the derived full width at half the maximum value of the pulse (FWHM) and the derived peak value of the PD pulse;
for a predetermined impedance, integrating the PD voltage pulse over time to generate a signal representative of magnitude of the charge in the PD pulse.

8. The apparatus of claim 7, further comprising an analog-to-digital converter for converting the output of the sensor into a digital format and a memory for storing the digital format of the sensor signal for later processing.

9. The apparatus of claim 7 wherein the spectrum analyzer is an analog swept frequency analyzer which generates digital output signals of the magnitude and frequency of components of the sensed PD pulse.

10. The apparatus of claim 7 wherein the spectrum analyzer is a digital frequency analyzer which generates digital output signals of the magnitude and frequency of components of the sensed PD pulse.
